(19) United States
(12) Patent Application Publication
(10) Pub. No.: US 2026/0013081 A1
(43) Pub. Date: Jan. 8, 2026

(54) SYSTEM AND METHOD FOR PROVIDING SUPPLEMENTAL POWER AND COOLING TO ONE OR MORE SERVER RACKS

(71) Applicant: Toyota Motor Engineering & Manufacturing North America, Inc., Plano, TX (US)

(72) Inventors: Chianing Wang, Mountain View, CA (US); Alexander T Pham, San Jose, CA (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/762,270

(22) Filed: Jul. 2, 2024

(51) Int. Cl. H05K 7/20; G06F 1/30; H01M 8/04119

(52) U.S. Cl. CPC H05K 7/20772; G06F 1/30; H01M 8/04156; H05K 7/20736; H05K 7/208; H05K 7/20836; H01M 2250/10

(57) ABSTRACT

Described herein are systems and methods for providing supplemental power and cooling to an electrical load, such as one or more server racks. In one example, a system includes a secondary power source that emits water as a by-product of operation and is connected to an electrical load that receives power from a primary power source and is cooled by a water-cooling system. The secondary power source is selectively configured to provide supplemental power to the electrical load when a condition has been met, wherein water produced during the operation of the secondary power source is provided to the water-cooling system.

### TECHNICAL FIELD

The subject matter described herein relates, in general, to systems and methods for providing supplemental power and cooling to one or more server racks and, more specifically, to systems and methods wherein the supplemental power is provided by a fuel cell that produces water as a by-product of operation.

### BACKGROUND

The background description provided is to present the context of the disclosure generally. Work of the inventor, to the extent it may be described in this background section, and aspects of the description that may not otherwise qualify as prior art at the time of filing, are neither expressly nor impliedly admitted as prior art against the present technology.

Some data centers offer computational resources provided by server racks that contain numerous graphics processing units (“GPUs”). Among other things, these GPUs can be used to perform machine learning (“ML”) based training to train a model and also machine learning inferencing, which is the process of using a trained model to generate predictions or classifications based on new data. However, recent demand for both training and inferencing of ML models has required ever more powerful and complex GPUs. These more powerful and complex GPUs not only require more power but also need more effective cooling.

### SUMMARY

This section generally summarizes the disclosure and is not a comprehensive explanation of its full scope or all its features.

In one embodiment, an electrical load, which may be one or more server racks, receives power from a primary power source. A water-cooling system cools the electrical load. In addition, the electrical load may be connected to a secondary power source, such as a hydrogen fuel cell, which emits water as a by-product of operation. The secondary power source is selectively configured to provide supplemental power to the electrical load when a condition has been met, such as when a power demand exceeds a power threshold and/or when the temperature of the electrical load exceeds a temperature threshold. Water that is produced during the operation of the secondary power source is provided to the water-cooling system to further assist with cooling the electrical load.

In another embodiment, a control system includes a processor and a memory in communication with the processor. The memory includes instructions that, when executed by the processor, cause the processor to actuate a secondary power source, such as a hydrogen fuel cell, to provide supplemental power to an electrical load that receives power from a primary power source when a condition has been met, such as when the electrical load exceeds a power demand threshold or temperature threshold. The secondary power source produces water as a by-product of operation, which is provided to a water-cooling system that cools the electrical load.

In yet another embodiment, a method includes the step of actuating a secondary power source to provide supplemental power to an electrical load that receives power from a primary power source when a condition has been met, wherein the secondary power source produces water as a by-product of operation. Like before, the water produced during the operation of the secondary power source is provided to a water-cooling system that cools the electrical load.

Further areas of applicability and various methods of enhancing the disclosed technology will become apparent from the description provided. The description and specific examples in this summary are intended for illustration only and are not intended to limit the scope of the present disclosure.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one example of a system for providing supplemental power and cooling to one or more server racks of a data center.

FIG. 2 illustrates another example of a system for providing supplemental power and cooling to one or more server racks of a data center.

FIG. 3 illustrates a more detailed view of a rear door heat exchanger for providing cooling to one or more server racks of a data center.

FIG. 4 illustrates a more detailed view of a direct-to-chip (“DTC”) cooling system for cooling one or more chips of a server rack of a data center.

FIG. 5 illustrates a block diagram of a control system that controls one or more systems or subsystems so as to provide supplemental power and cooling to one or more server racks of a data center.

FIG. 6 illustrates a method for providing supplemental power and cooling to one or more server racks of a data center.

### DETAILED DESCRIPTION

Described are systems and methods for providing supplemental power and cooling to one or more server racks. As will be described in more detail in the paragraphs that follow, a server rack may be powered by a primary power source, such as an electrical grid. In addition, the server rack may utilize a water-cooling system that essentially cools the server rack and, more specifically, may cool one or more GPUs and/or CPUs that may be found on individual servers of the server rack. In one example, when the server rack is powered solely by the primary power source, the water-cooling system may utilize a DTC cooling system to cool the GPUs and/or CPUs.

Situations may arise wherein the power draw of the one or more server racks and/or the heat generated by the server racks when in operation exceeds a threshold. Generally, this type of situation may arise when the GPUs and/or CPUs of the server rack are performing complex computations, such as during the training and/or inferencing of an ML model. When a temperature and/or power demand threshold is exceeded, a control system actuates a secondary power source, such as one or more hydrogen fuel cells, to provide supplemental power to the server rack. In addition, during the operation of the secondary power source, water may be produced as a by-product. Water generated by the secondary power source can be provided to the cooling system to enhance its ability to cool the server rack. Additionally, when the secondary power source is in operation, the controller may cause a secondary cooling system, such as a rear door heat exchanger, to supplement the cooling of the server rack. As such, the secondary power source not only acts as a way to supplement the power demand of the server racks but also provides additional cooling capabilities that will be beneficial when high computational loads are experienced.

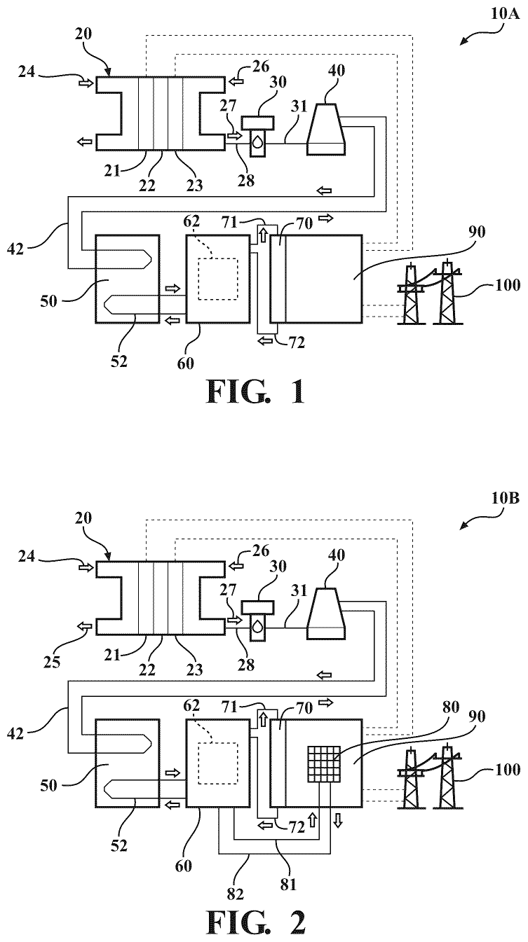

Referring to FIG. 1, illustrated is one example of a system 10A that provides both supplemental power and cooling to a server rack 90. Before covering the details of the supplemental power and cooling system of the system 10A, a brief description of the server rack 90 will be provided. The server rack 90 may be a single server rack or may be multiple server racks. The server rack 90 may include one or more rack servers, sometimes referred to as blades, which can include one or more components, such as random-access memory, storage, network interfaces, and power supplies. In addition, these electronic components can also include processing units, such as one or more GPUs and/or CPUs. In particular, GPUs may be used in the server rack 90 and are widely used in ML data centers due to their ability to handle complex and computationally intensive tasks required for training and running machine learning models.

Generally, the server rack 90 receives power from a primary power source 100. In one example, the primary power source 100 may be an electrical grid. However, it should be understood that the primary power source 100 can vary from application to application. As such, the primary power source 100 can vary significantly and can include any other source capable of producing power to power the server rack 90.

As mentioned before, the system 10A can provide both supplemental power and cooling to the server rack 90. In this example, supplemental power provided to the server rack 90 is generated by a secondary power source, which may be one or more hydrogen fuel cells 20. The hydrogen fuel cell 20 operates by converting hydrogen gas into electricity through a chemical reaction, with water being a by-product of this chemical reaction. As such, in this example, the hydrogen fuel cell 20 includes an anode 21, an electrolyte 22, and a cathode 23. As is well known, a hydrogen gas 24 enters into the anode 21 and is split into protons and electrons, and air 26 is provided to the cathode 23. The protons and electrons separated by the anode 21 take different paths to the cathode 23, with the protons moving through the electrolyte 22 to the cathode 23 and the electrons traveling through the external circuit, in this case, the server rack 90, to the cathode 23, thus creating a flow of electricity. The protons, electrons, and air 26 combine to produce water 27 as a by-product of the operation of the hydrogen fuel cell 20.

The water 27 produced by the operation of the hydrogen fuel cell 20 may be provided to a purifier 30 via a fluid connection 28. Generally, the purifier 30 can be a filter capable of filtering one or more impurities from the water 27. For example, in some cases, oil, dirt, environmental contamination, or other impurities may come into contact with the water 27, necessitating the need for the purifier 30. However, it should be understood that if the water 27 produced during the operation of the hydrogen fuel cell 20 is of the appropriate purity, the purifier 30 may not be necessary and may not form part of the system 10A. After being purified (if necessary), the water 27 is then provided to a cooling tower 40 via a fluid connection 31. Moreover, the cooling tower 40 forms part of a cooling system for cooling the server rack 90, which can include other components, such as a chiller 50, a cooling distribution unit 60, and a rear door heat exchanger 70.

In this example, the cooling tower 40 is connected to the chiller 50 via a condenser loop 42. In turn, the chiller 50 is connected to the cooling distribution unit 60 via a chilled water loop 52. The chiller 50 uses the principles of refrigeration to absorb heat from the water, providing effective cooling for the server rack 90. As such, water in the chilled water loop 52 enters an evaporator of the chiller 50, where heat is transferred from the water to a refrigerant. The chilled water is then sent to the cooling distribution unit 60, where it is distributed to one or more cooling systems, such as the rear door heat exchanger 70. The heat absorbed by the refrigerant in the evaporator of the chiller 50 is transferred to allow the refrigerant to absorb more heat. The low-pressure, high-temperature refrigerant moves from the evaporator to the motor-run compressor, which increases the pressure and temperature. After that, the refrigerant enters a condenser of the chiller 50. Water is then pumped into the cooling tower 40 to release the heat. After condensing, the refrigerant goes through an expansion valve to reduce pressure and temperature before returning to the evaporator, where the process begins again.

As mentioned, chilled water is provided from the chiller 50 to the cooling distribution unit 60, which functions to distribute the chilled water to one or more cooling systems. As such, the cooling distribution unit 60 includes the appropriate valves, piping, and other systems to appropriately and selectively direct chilled water to one or more cooling systems and return it to the chiller 50 via the chilled water loop 52. In addition, the cooling distribution unit 60 may have a control system 62 that can control the cooling distribution unit 60 and/or other systems and subsystems forming the system 10A. The control system 62 may be located within the cooling distribution unit 60, as shown, but can also be located separate and apart from the cooling distribution unit 60. Furthermore, the control system 62 may be located partially and/or completely remote from the system 10A.

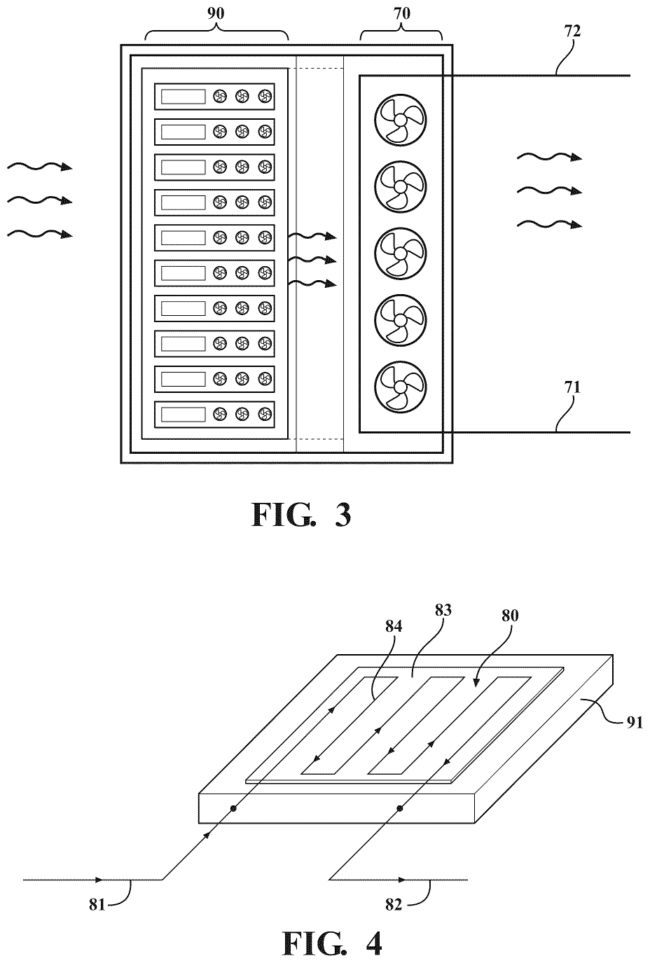

In this example, the system 10A shows one type of cooling system for cooling the server rack 90, namely, a rear door heat exchanger 70. Moreover, FIG. 3 illustrates a more detailed view of the rear door heat exchanger 70. Here, illustrated is the server rack 90 including several rack servers that generate heat during their operation. The rear door heat exchanger 70 is mounted to the back door of the server rack 90 where it is positioned to absorb heat expelled from the rack servers, which may be aided by the use of one or more fans. The rear door heat exchanger 70 receives chilled water from the cooling distribution unit 60 via a fluid line 71, which is then circulated through coils or plates. As hot air from the rack servers passes over these coils or plates, heat from the air is transferred to the water, which is then returned to the cooling distribution unit 60 via a fluid line 72, where it can be cooled again by the chiller 50.

Returning to FIG. 2, the control system 62, as mentioned previously, can monitor the power demand and/or heat generated by the operation of the server rack 90 to determine when supplemental power should be provided to the server rack 90. This can be based on a threshold power demand and/or temperature. When this threshold is exceeded, the control system 62 actuates the hydrogen fuel cell 20 to provide supplemental power to the server rack 90 and directs water 27 produced by the operation of the hydrogen fuel cell 20 to the cooling tower 40, which aids the cooling of the server rack 90. As such, by utilizing the hydrogen fuel cell 20 to provide supplemental power to the server rack 90, not only does the server rack 90 receive supplemental power, but also the cooling system of the server rack 90 is aided by the production of water provided to the cooling tower 40 produced as a by-product of the operation of the hydrogen fuel cell 20.

FIG. 2 illustrates another example of a system 10B for providing supplemental power and cooling to the server rack 90. Like reference numerals have been utilized to refer to like elements. As such, any description given of these elements when describing FIG. 1 is equally applicable to the system 10B and will not be described again. Broadly, the system 10B differs from that of the system 10A in that the system 10B includes two different systems for cooling the server rack 90. Moreover, in addition to the rear door heat exchanger 70, the system 10B also includes a DTC cooling system 80 for directly cooling one or more chips, such as GPUs, utilized by one or more rack servers forming the server rack 90.

FIG. 4 illustrates a more detailed view of the DTC cooling system 80. It should be noted that, in this example, only a single chip 91 is being cooled. However, it should be understood that the DTC cooling system 80 could be cooling numerous chips. Here, illustrated is a chip 91, which could be a GPU that may be found in a rack server. The DTC cooling system 80 includes a cooling plate 83 that includes a zigzag channel 84 that has an inlet line 81 that receives chilled water from the cooling distribution unit 60. The chilled water travels along the zigzag channel 84, transferring heat generated by the chip 91 to the water located within the zigzag channel 84. The water is then output to an outlet line 82, where it is returned to the cooling distribution unit 60, where the water can be chilled by the chiller 50.

Returning to FIG. 2, the control system 62, in this example, may direct the cooling distribution unit 60 to provide chilled water to the DTC cooling system 80 when the server rack 90 is receiving power from the primary power source 100. In a situation where the server rack 90 is receiving power from the primary power source 100 and not from the hydrogen fuel cell 20 (i.e., the secondary power source), the control system 62 may only be sending chilled water from the cooling distribution unit 60 to the DTC cooling system 80. As such, in this situation, only the DTC cooling system 80 would be cooling the server rack 90 and not the rear door heat exchanger 70.

However, in situations where the hydrogen fuel cell 20 is providing supplemental power to the server rack 90, the control system 62 may also direct the cooling distribution unit 60 to provide chilled water to both the DTC cooling system 80 and the rear door heat exchanger 70, maximizing the cooling of the server rack 90. As mentioned before, the production of water due to the operation of the hydrogen fuel cell 20 can be directed to the cooling tower 40, enhancing the ability of the chiller 50 to chill water provided to the DTC cooling system 80 and the rear door heat exchanger 70.

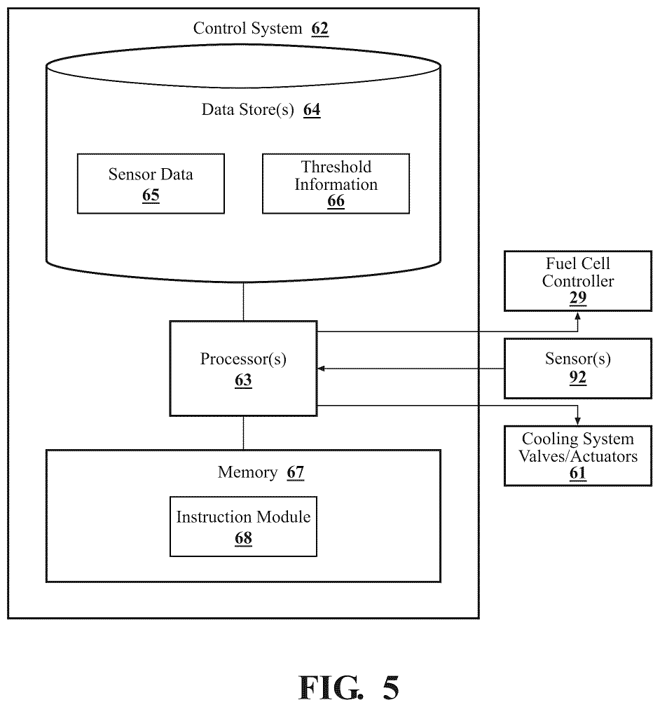

With reference to FIG. 5, one embodiment of the control system 62 for controlling one or more systems and or subsystems of the systems 10A and/or 10B of FIGS. 1 and 2, respectively, is further illustrated. As shown, the control system 62 includes one or more processor(s) 63. Accordingly, the processor(s) 63 may be a part of the control system 62, or the control system 62 may access the processor(s) 63 through a data bus or another communication path. In one or more embodiments, the processor(s) 63 is an application-specific integrated circuit that is configured to implement functions associated with an instruction module 68. In general, the processor(s) 63 is an electronic processor, such as a microprocessor, which is capable of performing various functions as described herein. In one embodiment, the control system 62 includes a memory 67 that stores the instruction module 68. The memory 67 is a random-access memory (RAM), read-only memory (ROM), a hard disk drive, a flash memory, or other suitable memory for storing the instruction module 68. The instruction module 68 is, for example, computer-readable instructions that, when executed by the processor(s) 63, cause the processor(s) 63 to perform the various functions disclosed herein.

Furthermore, in one embodiment, the control system 62 includes one or more data store(s) 64. The data store(s) 64 is, in one embodiment, an electronic data structure such as a database that is stored in the memory 67 or another memory and that is configured with routines that can be executed by the processor(s) 63 for analyzing stored data, providing stored data, organizing stored data, and so on. Thus, in one embodiment, the data store(s) 64 stores data used by the instructions module 68 in executing various functions. In one embodiment, the data store(s) 64 includes sensor data 65 and threshold information 66, along with, for example, other information that is used by the instruction module 68.

The sensor data 65 may include data collected from one or more sensors 92. In one example, the one or more sensors 92 may collect information related to the power demand of the server rack 90 and/or the heat generated during the operation of the server rack 90. Information regarding the heat can include the temperature of one or more components or areas near components making up the server rack 90, including GPUs and/or CPUs, coolant temperatures, air temperatures, etc. The threshold information 66 can include information regarding one or more conditions regarding the server rack 90. For example, the threshold information 66 can include a power threshold indicating the maximum amount of power that the server rack 90 should draw from the primary power source 100 and/or a temperature threshold indicating the maximum temperature of one or more components of the server rack 90. As will be explained later, when these thresholds are met and/or exceeded, the control system 62 will utilize a supplemental power source, such as the hydrogen fuel cell 20.

As mentioned before, the instruction module 68 includes instructions that cause the processor(s) 63 to perform any one of the methodologies disclosed herein. In one example, the instruction module 68 includes instructions that, when executed by the processor(s) 63, cause the processor(s) 63 to monitor the sensor data 65 collected by the sensors 92. As mentioned before, the sensor information can include information regarding the power drawn by the server rack 90 and/or temperature-related information caused by the operation of the server rack 90.

When the sensor information indicates that a condition has been met, such as a power draw from the server rack 90 exceeding a power threshold and/or a temperature of one or more components of the server rack 90 exceeding a temperature threshold stored in the threshold information 66, the instruction module 68 includes instructions that, when executed by the processor(s) 63, cause the processor to actuate the secondary power source, in this case, the hydrogen fuel cell 20. This may be accomplished by having the processor(s) 63 send one or more commands to a fuel cell controller 29 that controls the operation of the hydrogen fuel cell 20.

In addition, the instruction module 68 includes instructions that, when executed by the processor(s) 63, also cause the processor(s) 63 to control the cooling system of the systems 10A and or 10B. In particular, the processor(s) 63 may be able to control one or more valves, actuators, and pumps forming the cooling system and, in particular, the cooling distribution unit 60. For example, when the secondary power source is actuated, the processor(s) 63 may cause the cooling distribution unit 60 to send chilled water to one or more cooling systems, such as the rear door heat exchanger 70. As mentioned before, when the hydrogen fuel cell 20 is operating, the hydrogen fuel cell 20 produces water as a by-product of operation, which the cooling system can then utilize.

The instruction module 68 may also include instructions to continuously have the processor(s) 63 monitor the sensor data 65 to determine when one or more conditions are no longer met. For example, there may be situations where the power demand and/or the temperature of the server rack 90 falls below one or more thresholds. When this occurs, the instruction module 68 may cause the processor to turn off the secondary power source, in this case, the hydrogen fuel cell 25, via the fuel cell controller 29. Furthermore, the instruction module 68 may also cause the processor(s) 63 to adjust the cooling system. For example, when operating below a particular power or temperature threshold, the instruction module 68 may have a processor(s) 63 only send chilled water from the cooling distribution unit 60 to the DTC cooling system 80, but not the rear door heat exchanger 70 or vice versa.

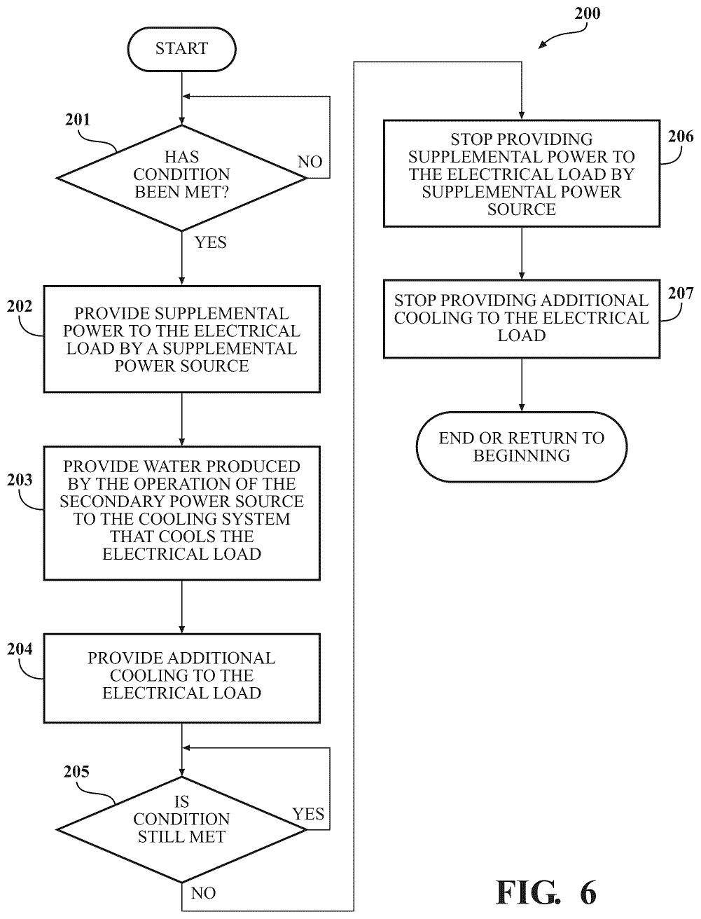

Referring to FIG. 6, a method 200 for controlling a system for providing supplemental power and cooling to a server rack is shown. The method 200 will be described from the viewpoint of the system 10B of FIG. 2 and the control system 62 of FIG. 5. However, it should be understood that this is just one example of implementing the method 200. While method 200 is discussed in combination with the control system 62, it should be appreciated that the method 200 is not limited to being implemented within the control system 62, but is instead one example of a system that may implement the method 200.

In step 201, the method 200 continuously monitors if a particular condition has been met. This may be achieved by having the instruction module 68 cause the processor(s) 63 to continuously monitor the sensor data 65 collected by the sensors 92. As mentioned before, the sensor data 65 can include information relating to the power drawn by the server rack 90 and/or temperature information related to the operation of the server rack 90. For example, the temperature information can include the temperature of components or near components forming the server rack 90 and/or the cooling system. For example, the operating temperature for a particular GPU or CPU could be monitored to determine if a certain condition has been met.

The condition can be met when a certain threshold has been passed. In one example, the threshold may be a power threshold that can relate to a certain amount of power drawn by the server rack 90. When the power drawn by the server rack 90 surpasses the power threshold, the condition can be satisfied. In another example, the threshold may be a temperature threshold related to the temperature of one or more particular components the server rack 90 and/or the cooling system. When the temperature of one or more particular components surpasses the temperature threshold, the condition can be satisfied.

If the condition has been satisfied, the method 200 proceeds to step 202, otherwise, the method 200 continues to monitor the sensor data 65 to determine if the condition has been met. In step 202, the instruction module 68 causes the processor(s) 63 to provide supplemental power to the electrical load, in this case, the server rack 90, by a supplemental power source. As explained previously, the supplemental power source can be the hydrogen fuel cell 20. In addition, as shown in step 203, water produced by the operation of the secondary power source (i.e., the hydrogen fuel cell 20) can be provided to the cooling system, in this case, the cooling tower 40.

In step 204, the instruction module 68 causes the processor(s) 63 to provide supplemental cooling to the electrical load, in this case, the server rack 90. This may be achieved by having the processor(s) 63 actuate one or more valves 61 of the cooling distribution unit 60. In one example, the supplemental cooling may involve providing chilled water to the rear door heat exchanger 70 to supplement the cooling provided by the DTC cooling system 80. As explained previously, in one example, when the server rack 90 is only receiving power from the primary power source 100, chilled water may only be provided to the DTC cooling system 80 by the cooling distribution unit 60. When supplemental power is provided to the server rack 90 from the hydrogen fuel cell 20, the processor may control the cooling distribution unit 60 to also send chilled water to the rear door heat exchanger 70 to provide supplemental cooling to the server rack 90.

It should be noted that the condition, either related to the power drawn by the server rack 90 and/or the temperature of one or more of the server rack 90 and/or the cooling system, may be continuously monitored, as indicated in step 205. If the condition is still met, supplemental power provided by the hydrogen fuel cell 20 and supplemental cooling provided by sending chilled water to the rear door heat exchanger 70 will continue.

However, when the condition is no longer met, the method 200 proceeds to step 206, wherein the instruction module 68 causes the processor(s) 63 to shut down the secondary power source (i.e., the hydrogen fuel cell 20) as shown in step 206 and stop providing additional cooling to cool the electrical load by shutting the flow of chilled water to the rear door heat exchanger 70, as shown in step 207. Thereafter, the method 200 may either stop or return to step 201.

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any processing system or another apparatus adapted for carrying out the methods described herein is suited. A typical combination of hardware and software can be a processing system with computer-usable program code that, when being loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. These elements can also be embedded in an application product, which comprises all the features enabling the implementation of the methods described herein and which, when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, module as used herein includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object-oriented programming language such as Java™, Smalltalk, C++, or the like, and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. A system comprising:
a secondary power source that emits water as a by-product of operation and is connected to an electrical load that receives power from a primary power source and is cooled by a water-cooling system; and
the secondary power source is selectively configured to provide supplemental power to the electrical load when a condition has been met, wherein water produced during the operation of the secondary power source is provided to the water-cooling system.

2. The system of claim 1, wherein the condition is at least one of:
when a power demand by the electrical load has exceeded a power threshold; and
when a temperature of the electrical load exceeds a temperature threshold.

3. The system of claim 1, wherein the water-cooling system further comprises:
a primary cooling system that cools the electrical load when receiving power from the primary power source; and
a secondary cooling system that cools the electrical load when the electrical load receives the supplemental power from the secondary power source, the cooling system uses water generated by the secondary power source when providing the supplemental power to the electrical load.

4. The system of claim 3, wherein:
the primary cooling system is a direct-to-chip cooling system that cools one or more chips that form the electrical load; and
the secondary cooling system is a rear door heat exchanger for cooling a server rack.

5. The system of claim 1, wherein the electrical load is one or more server racks comprising one or more servers that include one or more chips.

6. The system of claim 5, wherein the one or more chips include one or more graphics processing units.

7. The system of claim 5, wherein the server racks provide computational resources for artificial intelligence training or inferencing.

8. The system of claim 1, wherein the cooling system comprises:
a cooling tower configured to receive water generated by the secondary power source when providing power to the electrical load;
a chiller fluidly connected to the cooling tower via a condenser loop;
a primary cooling system fluidly connected to the chiller via a chilled water loop, the primary cooling system cools the electrical load when receiving the power from the primary power source; and
a secondary cooling system fluidly connected to the chiller via the chilled water loop that cools the electrical load when receiving the supplemental power from the secondary power source.

9. A control system comprising:
a processor; and
a memory in communication with the processor, the memory having instructions that, when executed by the processor, cause the processor to:
actuate a secondary power source to provide supplemental power to an electrical load that receives power from a primary power source when a condition has been met, wherein the secondary power source produces water as a by-product of operation, the water produced during the operation of the secondary power source is provided to a water-cooling system that cools the electrical load.

10. The control system of claim 9, wherein the condition is at least one of:
when a power demand by the electrical load has exceeded a power threshold; and
when a temperature of the electrical load exceeds a temperature threshold.

11. The control system of claim 9, wherein the memory further comprises instructions that, when executed by the processor, cause the processor to
control the cooling system to cool the electrical load using a primary cooling system when the electrical load receives power from the primary power source; and
control the cooling system to cool the electrical load using a secondary cooling system when the electrical load receives the supplemental power from the secondary power source, the cooling system uses the water generated by the secondary power source when providing the supplemental power to the electrical load.

12. The control system of claim 11, wherein:
the primary cooling system is a direct-to-chip cooling system that cools one or more chips that form the electrical load; and
the secondary cooling system is a rear door heat exchanger for cooling a server rack.

13. The control system of claim 9, wherein the electrical load is one or more server racks comprising one or more servers that include one or more chips.

14. The control system of claim 13, wherein the one or more chips include one or more graphics processing units.

15. The control system of claim 13, wherein the server racks provide computational resources for artificial intelligence training or inferencing.

16. The control system of claim 9, wherein the cooling system comprises:
a cooling tower configured to receive the water generated by the secondary power source when providing power to the electrical load;
a chiller fluidly connected to the cooling tower via a condenser loop;
a primary cooling system fluidly connected to the chiller via a chilled water loop, the primary cooling system cools the electrical load when receiving the power from the primary power source; and
a secondary cooling system fluidly connected to the chiller via the chilled water loop that cools the electrical load when receiving the supplemental power from the secondary power source.

17. A method comprising:
actuating a secondary power source to provide supplemental power to an electrical load that receives power from a primary power source when a condition has been met, wherein the secondary power source produces water as a by-product of operation, the water produced during the operation of the secondary power source is provided to a water-cooling system that cools the electrical load.

18. The method of claim 17, wherein the condition is at least one of:
when a power demand by the electrical load has exceeded a power threshold; and
when a temperature of the electrical load exceeds a temperature threshold.

19. The method of claim 17, further comprising:
controlling the cooling system to cool the electrical load using a primary cooling system when the electrical load receives power from the primary power source; and
controlling the cooling system to cool the electrical load using a secondary cooling system when the electrical load receives the supplemental power from the secondary power source, the cooling system uses the water generated by the secondary power source when providing the supplemental power to the electrical load.

20. The method of claim 19, wherein:
the primary cooling system is a direct-to-chip cooling system that cools one or more chips that form the electrical load; and
the secondary cooling system is a rear door heat exchanger for cooling a server rack.
